(19) United States
(12) Patent Application Publication
(10) Pub. No.: US 2026/0256019 A1
(43) Pub. Date: Aug. 27, 2026

(54) SEMICONDUCTOR DEVICE AND MANUFACTURING METHOD THEREOF

(71) Applicant: NANYA TECHNOLOGY CORPORATION, New Taipei City (TW)

(72) Inventor: Hui-Lin CHEN, New Taipei City (TW)

(21) Appl. No.: 19/064,705

(22) Filed: Feb. 27, 2025

(51) Int. Cl. H10W 74/10; H10W 42/00; H10W 74/01; H10W 72/20

(52) U.S. Cl. CPC H10W 74/137; H10W 42/121; H10W 74/01; H10W 74/147; H10W 72/263; H10W 72/267

(57) ABSTRACT

A semiconductor device includes a substrate, a dielectric layer, a metal line layer, a passivation structure, an active bump, and a dummy bump. The dielectric layer is over the substrate. The metal line layer is over the dielectric layer, in which the metal line layer includes a via portion penetrating the dielectric layer. The passivation structure is over the metal line layer, in which the passivation structure includes a protrusion surrounded by the via portion of the metal line layer and a horizontal portion of the protrusion. The active bump penetrates the passivation structure to electrically connect to the metal line layer. The dummy bump is over the passivation structure, wherein the dummy bump overlaps the protrusion of the passivation structure in a cross-section view.

### BACKGROUND

### Field of Disclosure

The present disclosure relates to a semiconductor device and a manufacturing method thereof.

### Description of Related Art

A conventional flip-chip structure includes a substrate, a metal line layer formed over the substrate, a passivation layer over the substrate, an active bump electrically connected to the metal line layer, and a dummy bump formed over the passivation layer. The flip-chip structure may be bonded to a package substrate, such as printed circuit board, by a bonding process. During the bonding process, the flip-chip structure is pressed against the package substrate, and the stress caused by the bonding process may damage the flip-chip structure, such as the passivation layer of the flip-chip structure. Therefore, there is a need to reduce the damage caused by the bonding process to the flip-chip structure.

### SUMMARY

Some embodiments of the present disclosure provides a semiconductor device including a substrate, a dielectric layer, a metal line layer, a passivation structure, an active bump, and a dummy bump. The dielectric layer is over the substrate. The metal line layer is over the dielectric layer, in which the metal line layer includes a via portion penetrating the dielectric layer. The passivation structure is over the metal line layer, in which the passivation structure includes a protrusion surrounded by the via portion of the metal line layer and a horizontal portion of the protrusion. The active bump penetrates the passivation structure to electrically connect to the metal line layer. The dummy bump is over the passivation structure, wherein the dummy bump overlaps the protrusion of the passivation structure in a cross-section view.

In some embodiments, a bottom surface of the horizontal portion and a sidewall of the protrusion of the passivation structure defines a corner, and the dummy bump further overlaps the corner in the cross-section view.

In some embodiments, the passivation structure has a dual-layer structure.

In some embodiments, the passivation structure includes a buffer layer, and a passivation layer over the buffer layer, in which a malleability of the passivation layer is lower than a malleability of the buffer layer.

In some embodiments, a bottommost surface of the passivation layer is higher than a topmost surface of the metal line layer.

In some embodiments, the protrusion of the passivation structure has a void.

In some embodiments, the passivation structure includes a passivation layer and a buffer layer over the passivation layer, in which a malleability of the passivation layer is lower than a malleability of the buffer layer.

In some embodiments, a thickness of the passivation layer is less than a thickness of the buffer layer.

In some embodiments, the passivation structure further includes an organic layer between the buffer layer and the dummy bump, in which a malleability of the organic layer is higher than the malleability of the buffer layer.

In some embodiments, the protrusion of the passivation structure comprises a portion of the organic layer.

Some embodiments of the present disclosure provide a manufacturing method of a semiconductor device, including forming a dielectric layer having an opening over a first substrate, forming a metal line layer lining the dielectric layer and the opening, forming a passivation structure over the metal line layer, in which the passivation structure overfills the opening and forms a protrusion in the opening and a horizontal portion over the protrusion, forming an active bump penetrating through the passivation structure to electrically connect the metal line layer; and forming a dummy bump over the passivation structure, in which the dummy bump overlaps the protrusion of the passivation structure in a cross-section view.

In some embodiments, a bottom surface of the horizontal portion and a sidewall of the protrusion of the passivation structure define a corner, and the dummy bump further overlaps the corner in the cross-section view.

In some embodiments, forming the passivation structure includes forming a buffer layer over the metal line layer and overfilling the opening, and forming a passivation layer over the buffer layer, and a malleability of the passivation layer is lower than a malleability of the buffer layer.

In some embodiments, forming the passivation structure further includes performing a planarization process to the buffer layer prior to forming the passivation layer.

In some embodiments, a void is formed in the protrusion of the passivation structure.

In some embodiments, a bottommost surface of the passivation layer is higher than a topmost surface of the metal line layer.

In some embodiments, forming the passivation structure includes forming a passivation layer lining the metal line layer, and forming a buffer layer lining the passivation layer, in which a malleability of the buffer layer is higher than a malleability of the passivation layer.

In some embodiments, the protrusion of the passivation structure includes a portion of the passivation layer and a portion of the buffer layer.

In some embodiments, forming the passivation structure further includes forming an organic layer over the buffer layer and overfilling the opening, wherein a malleability of the organic layer is higher than a malleability of the buffer layer.

In some embodiments, the method further includes bonding the active bump and the dummy bump to a second substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-9 illustrate cross-section views of a manufacturing method of a semiconductor device in some embodiments of the present disclosure.

FIGS. 10-15 illustrate cross-section views of a manufacturing method of a semiconductor device in some other embodiments of the present disclosure.

### DETAILED DESCRIPTION

The present disclosure is related to manufacturing method of a flip-chip structure. The flip-chip structure includes a passivation structure to prevent moisture for permeating into the circuit of the flip-chip structure. The manufacturing method in the present disclosure may reduce the possibility of the crack of the passivation structure to enhance the moisture isolation of the flip-chip structure.

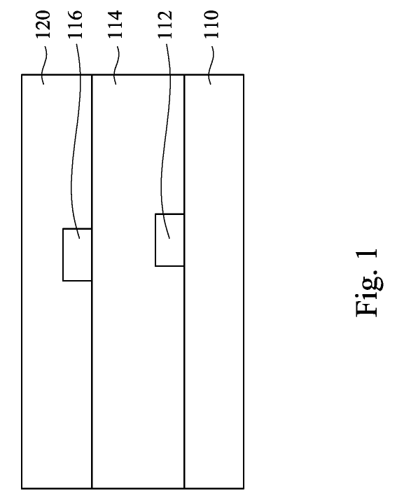

FIGS. 1-9 illustrate cross-section views of a manufacturing method of a semiconductor device in some embodiments of the present disclosure. Referring to FIG. 1, a substrate 110, an active device 112, an interconnect structure 114, and a metal pad 116 are provided. The substrate 110 may be a semiconductor substrate, such as a silicon substrate. The active device 112, such as transistors, may be formed on the substrate 110. An interconnect structure 114 may be formed over and electrically connected with the active device 112. The metal pad 116 may be formed over and electrically connected with the interconnect structure 114.

Subsequently, the dielectric layer 120 is formed over the substrate 110, the active device 112, the interconnect structure 114, and the metal pad 116. In some embodiments, the dielectric layer 120 may be silicon oxide, silicon nitride, or combinations thereof. In some embodiments, the dielectric layer 120 may be a stack of dielectric sub-layers.

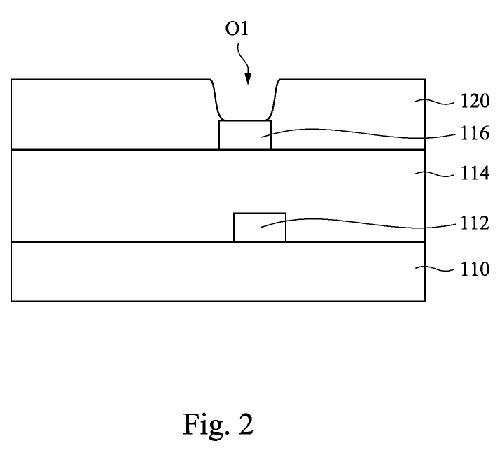

Referring to FIG. 2, a patterning process is performed, such that the dielectric layer 120 has an opening O1 exposing the metal pad 116. In some embodiments, the patterning process may be a photolithography process.

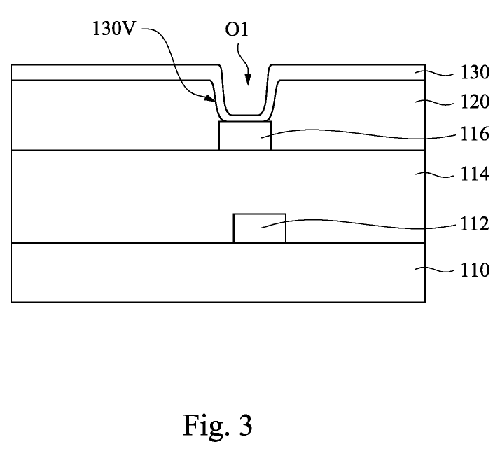

Referring to FIG. 3, a metal line layer 130 is formed lining the dielectric layer 120 and the opening O1, and the metal line layer 130 includes a via portion 130V penetrating the dielectric layer 120 accordingly. The metal line layer 130 is over the dielectric layer 120 and the substrate 110 and electrically connected with the active device 112 through the interconnect structure 114 and the metal pad 116. In some embodiments, the metal line layer 130 is made of metal, such as aluminum. In some embodiments, the metal line layer 130 is formed by chemical vapor deposition, atomic layer deposition, or the like.

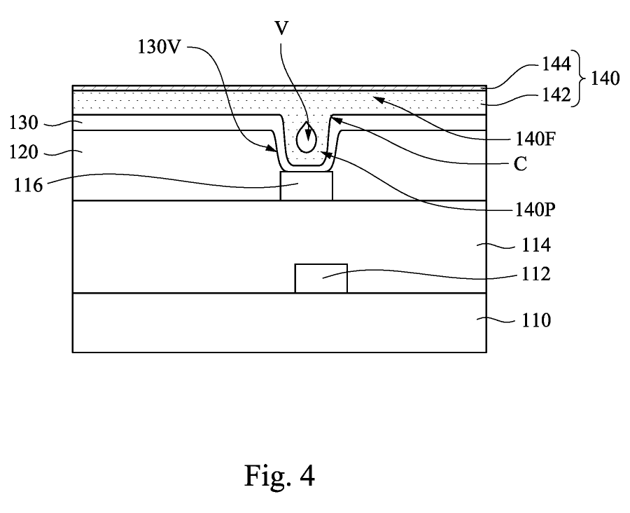

Referring to FIG. 4, a passivation structure 140 is formed over the metal line layer 130. The passivation structure 140 overfills the opening O1 and forms a protrusion 140P in the opening O1 protruding toward the substrate 110 and a horizontal portion 140F over the protrusion 140P and extending over a top surface of the dielectric layer 120. The bottom surface of the horizontal portion 140F and a sidewall of the protrusion 140P of the passivation structure 140 define a corner C. In some embodiments, the passivation structure 140 has a dual-layer structure, and the passivation structure 140 includes a buffer layer 142 and a passivation layer 144 over the buffer layer 142. Specifically, a buffer layer 142 is formed over the metal line layer 130 and overfilling the opening O1 first by suitable deposition process, and then the passivation layer 144 is formed over the buffer layer 142. The malleability of the passivation layer 144 is lower than the malleability of the buffer layer 142, and the moisture absorption of the passivation layer 144 is lower than the moisture absorption of the buffer layer 142. That is, the passivation layer 144 may be used for isolate the semiconductor structure from the moisture. In some embodiments, the buffer layer 142 is a silicon oxide. In some embodiments, the buffer layer 142 is formed by a deposition process, such as physical vapor deposition, using TEOS (tetraethoxysilane) as a precursor. In some embodiments, a void V may be formed in the protrusion 140P of the passivation structure 140 during forming the buffer layer 142, and the protrusion 140P of the passivation structure 140 has the void V. In some embodiments, the passivation layer 144 is a silicon nitride. In some embodiments, the passivation layer 144 is formed by a deposition process, such as chemical vapor deposition or atomic layer deposition. In some embodiments, the thickness of the passivation layer 144 is less than the thickness of the buffer layer 142. In some embodiments, a planarization process, such as chemical mechanical planarization, may be performed prior to forming the passivation layer 144, to planarize the surface of the passivation layer 144.

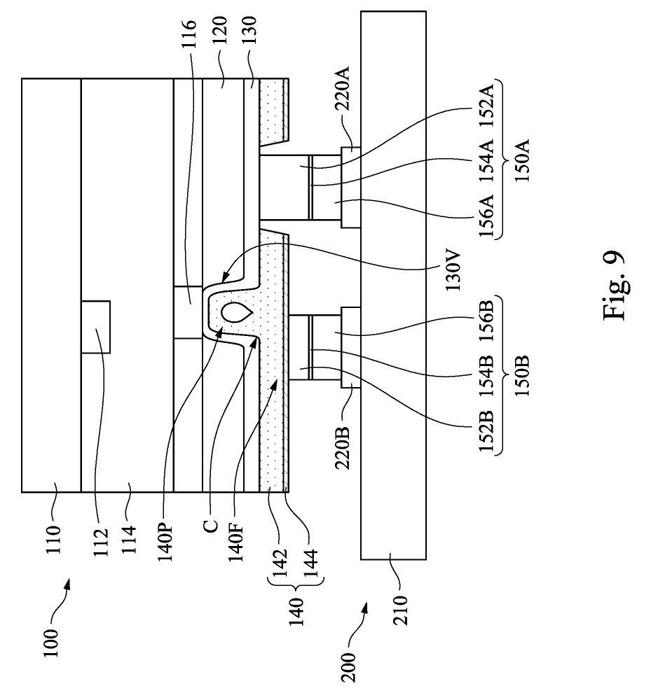

The passivation layer 144 with better moisture isolation is a thin layer compared to the buffer layer 142, and thus is vulnerable if the passivation layer 144 is not well protected or the passivation layer 144 is formed at vulnerable position, such as formed at the corner C defining by the bottom surface of the horizontal portion 140F and the sidewall of the protrusion 140P of the passivation structure 140. In the embodiment shown in FIG. 4, the passivation layer 144 is formed after forming the buffer layer 142 overfilling the opening O1, and is a substantially flat layer. That is, a bottommost surface of the passivation layer 144 is higher than a topmost surface of the metal line layer 130. Therefore, the protrusion 140P of the passivation structure 140 in the opening O1 includes a portion of the buffer layer 142, and is free of the passivation layer 144. The flat passivation layer 144 is less likely damaged during the subsequent process, such as the bonding process shown in FIG. 9, thereby the moisture isolation of the passivation structure 140 still remaining at the same level after the bonding process.

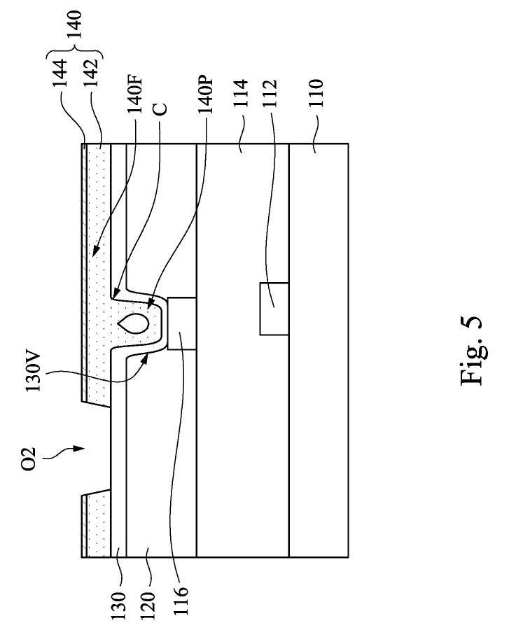

Referring to FIG. 5, a patterning process is performed, such that the passivation structure 140 has an opening O2 exposing the metal line layer 130. In some embodiments, the patterning process may be a photolithography process.

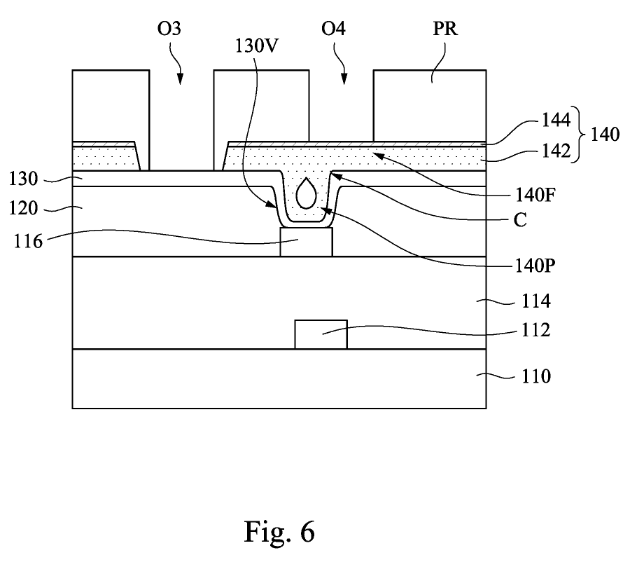

Referring to FIG. 6, a patterned mask layer PM is formed over the passivation structure 140 and the metal line layer 130. The patterned mask layer PM has an opening O3 and an opening O4. The opening O3 of the patterned mask layer PM overlap the opening O2 of the passivation structure 140 in the cross-section view, and exposes the metal line layer 130. The opening O4 of the patterned mask layer PM exposes the passivation structure 140. In some embodiments, the opening O4 of the patterned mask layer PM may overlap the protrusion 140P of the passivation structure 140 in the cross-section view. In some embodiments, the patterned mask layer PM may be a photoresist layer or a dielectric layer patterned by a photolithography process.

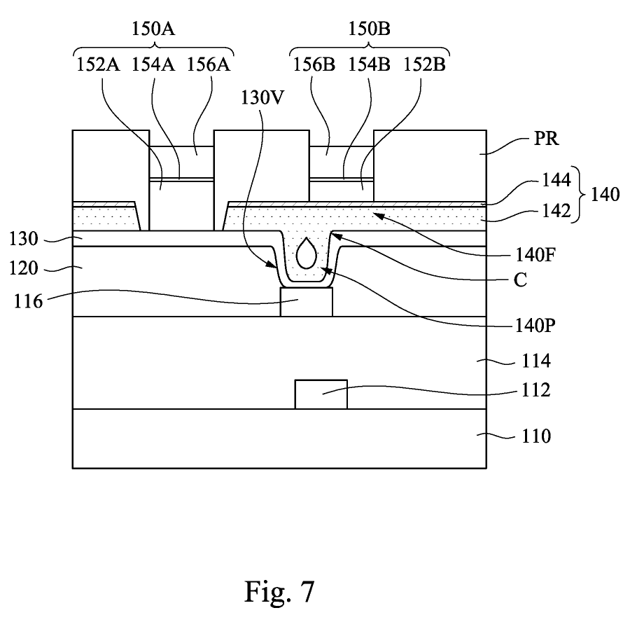

Referring to FIG. 7, an active bump 150A is formed in the opening O3 of the patterned mask layer PM and a dummy bump 150B is formed in the opening O4 of the patterned mask layer PM. Since the opening O3 and the opening O4 defines the locations of the active bump 150A and the dummy bump 150B, the dummy bump 150B is also formed over the protrusion of the passivation structure 140. The active bump 150A is formed to penetrate through the passivation structure 140 to electrically connect the metal line layer 130. The dummy bump 150B is formed over the passivation structure 140, and is electrically isolated from the metal line layer 130 by the passivation structure 140. The active bump 150A will be used to electrically connect the substrate 110 to another substrate during the subsequent process, such as the bonding process shown in FIG. 9, while the dummy bump 150B will not be used for electrical connection. The dummy bump 150B may be used for support between the substrate 110 and another substrate.

In some embodiments, the active bump 150A may include a conductive pillar 152A, a coated layer 154A over the conductive pillar 152A, and a solder 156A over the coated layer 154A, and the dummy bump 150B may include a conductive pillar 152B, a coated layer 154B over the conductive pillar 152B, and a solder 156B over the coated layer 154B. Specifically, the conductive pillar 152A and the conductive pillar 152B may be formed in the opening O3 and the opening O4 of the patterned mask layer PM respectively and simultaneously. The coated layer 154A and the coated layer 154B are formed over the conductive pillar 152A and the conductive pillar 152B respectively and simultaneously, and the solder 156A and the solder 156B are formed over the conductive pillar 152A and the conductive pillar 152B respectively and simultaneously. In some embodiments, the conductive pillar 152A, the conductive pillar 152B, the coated layer 154A, the coated layer 154B, the solder 156A and the solder 156B may be formed by electroplating. In some embodiments, the conductive pillar 152A, the conductive pillar 152B, the coated layer 154A, the coated layer 154B, the solder 156A and the solder 156B may be made of metal. For example, the conductive pillar 152A and the conductive pillar 152B may be made of copper, the coated layer 154A and the coated layer 154B may be made of nickel, and the solder 156A and the solder 156B may be made of tin-silver. It is noted that the structure and the manufacturing method of the active bump 150A and the dummy bump 150B are not limited to the present disclosure, and other suitable structure and manufacturing method of the active bump 150A and the dummy bump 150B may be used.

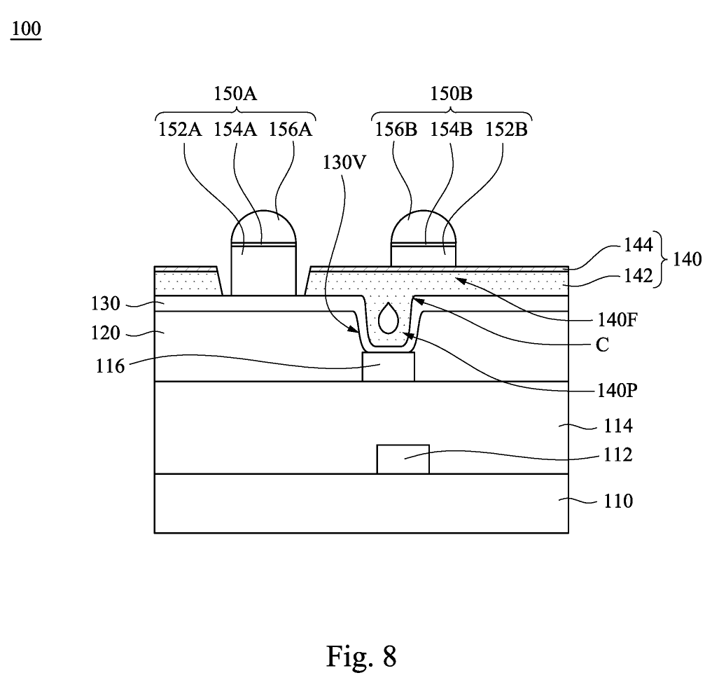

Referring to FIG. 8, the patterned mask layer PM is removed, and then the solder 156A and the solder 156B may be reflowed, such that the solder 156A and the solder 156B are formed in the ball shape. In some embodiments, the patterned mask layer PM is removed by stripping or ashing.

A resulting flip-chip structure 100 is shown in FIG. 8. The flip-chip structure 100 includes a substrate 110, a dielectric layer 120, a metal line layer 130, a passivation structure 140, an active bump 150A, and a dummy bump 150B. The dielectric layer 120 is over the substrate 110. The metal line layer 130 is over the dielectric layer 120, in which the metal line layer 130 includes a via portion 130V penetrating the dielectric layer 120. The passivation structure 140 is over the metal line layer 130, in which the passivation structure 140 includes a protrusion 140P surrounded by the via portion 130V of the metal line layer 130 and a horizontal portion 140F over the protrusion 140P. The active bump 150A penetrates the passivation structure 140 to electrically connect to the metal line layer 130. The dummy bump 150B is over the passivation structure 140, in which the dummy bump 150B overlaps the protrusion 140P of the passivation structure 140. In some embodiments, the dummy bump 150B further overlaps the corner C defining by the bottom surface of the horizontal portion 140F and the sidewall of the protrusion 140P of the passivation structure 140. In some embodiments, the flip-chip structure 100 can also be referred to as a semiconductor die 100.

In the embodiments shown in FIG. 9, the passivation structure 140 includes a buffer layer 142 and a passivation layer 144. The buffer layer 142 is over the metal line layer 130 and the protrusion 140P of the passivation structure 140 includes a portion of the buffer layer 142. The passivation layer 144 is over the buffer layer 142, and is between the buffer layer 142 and the dummy bump 150B.

Referring to FIG. 9, the flip-chip structure 100 is flipped upside down, and then the flip-chip structure 100 is bonded to a substrate 200 by the active bump 150A and the dummy bump 150B. The substrate 200 comprises a conductive pad 210A and a conductive pad 210B. Specifically, the backside surface of the flip-chip structure 100 is held by suction using a bonding tool (not shown), and the flip-chip structure 100 is pressed against the substrate 200 at high temperature. The conductive pad 210A of the substrate 200 is bonded to the active bump 150A of the flip-chip structure 100, and the conductive pad 210B of the substrate 200 is bonded to the dummy bump 150B of the flip-chip structure 100. In some embodiments, the substrate 200 may be a package substrate, such as a printed circuit board.

Generally speaking, during the bonding process of the flip-chip structure 100 and the substrate 200, the stress of the bonding process may cause the damage of the passivation layer 144 if the passivation layer 144 is not well protected or the passivation layer 144 is formed at vulnerable position, such as formed at the corner C and overlapping the dummy bump 150B. Specifically, the stress of the bonding process may concentrate at the active bump 150A and the dummy bump 150B. The dummy bump 150B overlapping the protrusion 140P of the passivation structure 140, especially the corner C, may lead to the stress concentration at the corner C, and cause the crack of the passivation layer 144 at the corner C. In the embodiment shown in FIGS. 1-9, since the passivation layer 144 is formed as a flat layer, and the stress of the passivation layer 144 may be evenly distributed during the bonding process. The passivation layer 144 is less likely damaged during the bonding process, thereby the moisture isolation of the passivation structure 140 still remaining at the same level after the bonding process.

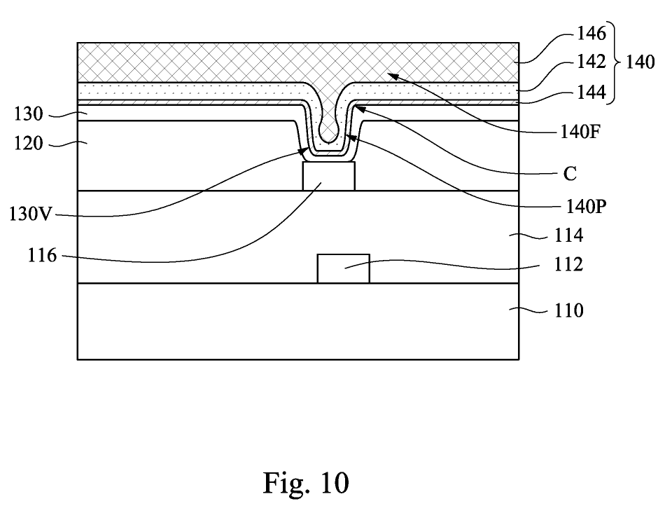

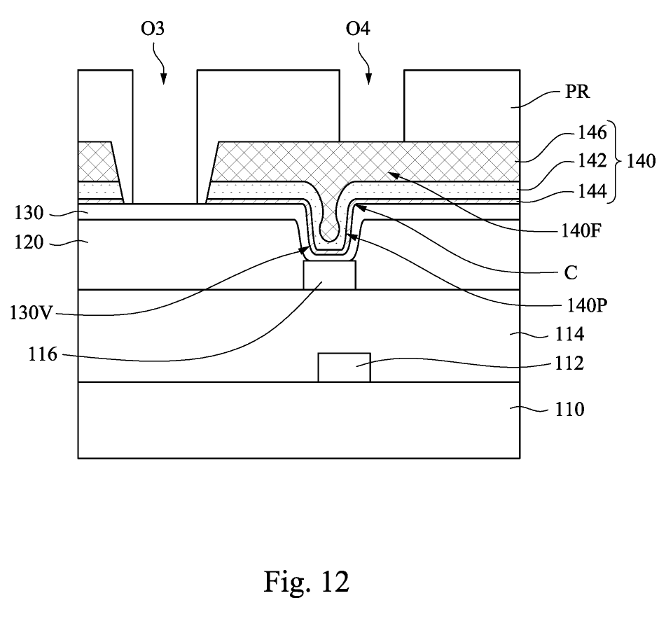

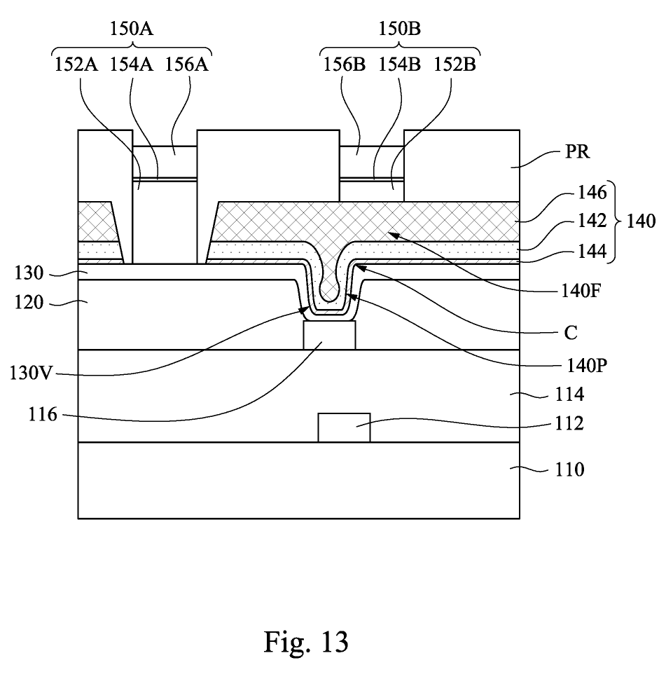

FIGS. 10-15 illustrate cross-section views of a manufacturing method of a semiconductor device in some other embodiments of the present disclosure. The processes illustrated in FIGS. 10-15 may be continued after the processes illustrated in FIGS. 1-3 have been complete.

Referring to FIG. 10, a passivation structure 140 is formed over the metal line layer 130. The passivation structure 140 overfills the opening O1 and forms a protrusion 140P in the opening O1 protruding toward the substrate 110 and a horizontal portion 140F over the protrusion 140P and extending over a top surface of the dielectric layer 120. The bottom surface of the horizontal portion 140F and a sidewall of the protrusion 140P of the passivation structure 140 define a corner C. In some embodiments, the passivation structure 140 includes a passivation layer 144, a buffer layer 142 over the passivation layer 144, and an organic layer 146. Specifically, the passivation layer 144 is formed lining the metal line layer 130, the buffer layer 142 is formed lining the passivation layer 144, and the organic layer 146 is formed over the buffer layer 142 and overfilling the opening O1. The malleability of the passivation layer 144 is lower than the malleability of the buffer layer 142, and the moisture absorption of the passivation layer 144 is lower than the moisture absorption of the buffer layer 142. That is, the passivation layer 144 may be used for isolate the semiconductor structure from the moisture. The malleability of the organic layer 146 is higher than the malleability of the buffer layer 142. In some embodiments, the passivation layer 144 is a silicon nitride. In some embodiments, the passivation layer 144 is formed by a deposition process, such as chemical vapor deposition or atomic layer deposition. In some embodiments, the buffer layer 142 is a silicon oxide. In some embodiments, the buffer layer 142 is formed by a deposition process, such as atomic layer deposition. In some embodiments, the thickness of the passivation layer 144 is less than the thickness of the buffer layer 142. In some embodiments, the organic layer 146 may be made of common photoresist material, such as polyimide. In some embodiments, the organic layer 146 may be formed by spin coating.

The passivation layer 144 with better moisture isolation is a thin layer compared to the buffer layer 142, and thus is vulnerable if the passivation layer 144 is not well protected or the passivation layer 144 is formed at vulnerable position, such as formed at the corner C defining by the bottom surface of the horizontal portion 140F and the sidewall of the protrusion 140P of the passivation structure 140. In the embodiment shown in FIG. 10, the passivation layer 144 is formed at the corner C and is well protected by the buffer layer 142. The malleability of the buffer layer 142 is between the malleability of the passivation layer 144 and the malleability of the organic layer 146. Therefore, the buffer layer 142 is able to provide a buffer from the stress from the subsequent process, such as the bonding process shown in FIG. 9, and the relative replacement between the passivation layer 144 and the organic layer 146 is reduced. The passivation layer 144 is less likely damaged or cracked, thereby the moisture isolation of the passivation structure 140 still remaining at the same level after the bonding process.

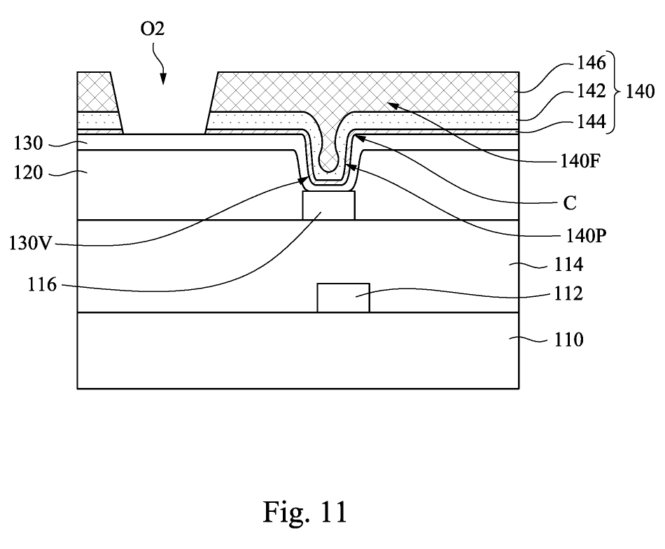

Referring to FIGS. 11-14, an active bump 150A and a dummy bump 150B are formed. The manufacturing method and the structure of the active bump 150A and the dummy bump 150B in FIGS. 11-14 may be similar to the manufacturing method of the active bump 150A and the dummy bump 150B in FIGS. 5-8, and thus detailed descriptions are not repeatedly described herein.

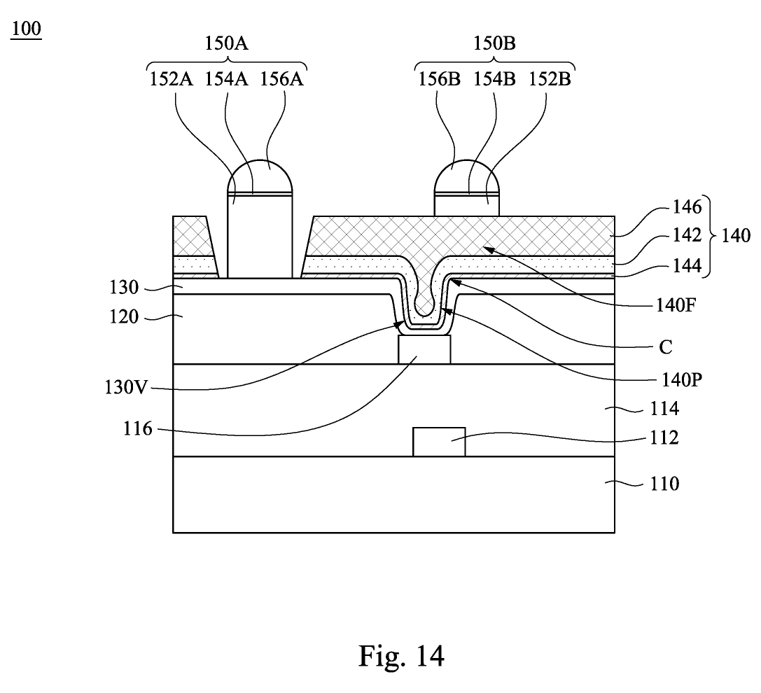

A resulting flip-chip structure 100 is shown in FIG. 14. The flip-chip structure 100 includes a substrate 110, a dielectric layer 120, a metal line layer 130, a passivation structure 140, an active bump 150A, and a dummy bump 150B. The dielectric layer 120 is over the substrate 110. The metal line layer 130 is over the dielectric layer 120, in which the metal line layer 130 includes a via portion 130V penetrating the dielectric layer 120. The passivation structure 140 is over the metal line layer 130, in which the passivation structure 140 includes a protrusion 140P surrounded by the via portion 130V of the metal line layer 130 and a horizontal portion 140F over the protrusion 140P. The active bump 150A penetrates the passivation structure 140 to electrically connect to the metal line layer 130. The dummy bump 150B is over the passivation structure 140, in which the dummy bump 150B overlaps the protrusion 140P of the passivation structure 140. In some embodiments, the dummy bump 150B further overlaps the corner C defining by the bottom surface of the horizontal portion 140F and the sidewall of the protrusion 140P of the passivation structure 140. In some embodiments, the flip-chip structure 100 can also be referred to as a semiconductor die 100.

In the embodiments shown in FIG. 14, the passivation structure 140 includes a buffer layer 142, a passivation layer 144, and an organic layer 146. The buffer layer 142 is over the metal line layer 130. The passivation layer 144 is between the buffer layer 142 and the metal line layer 130. The organic layer 146 is over the buffer layer 142, and is between the buffer layer 142 and the dummy bump 150B. The protrusion 140P of the passivation structure 140 includes a portion of the buffer layer 142, a portion of the passivation layer 144, and a portion of the organic layer 146.

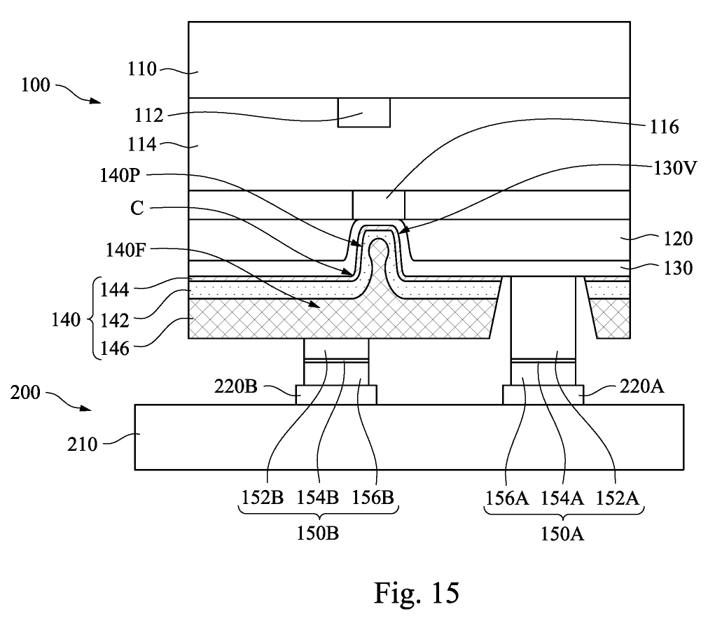

Referring to FIG. 15, the flip-chip structure 100 is flipped upside down, and then the flip-chip structure 100 is bonded to a substrate 200 by the active bump 150A and the dummy bump 150B. The substrate 200 comprises a conductive pad 210A and a conductive pad 210B. Specifically, the backside surface of the flip-chip structure 100 is held by suction using a bonding tool (not shown), and the flip-chip structure 100 is pressed against the substrate 200 at high temperature. The conductive pad 210A of the substrate 200 is bonded to the active bump 150A of the flip-chip structure 100, and the conductive pad 210B of the substrate 200 is bonded to the dummy bump 150B of the flip-chip structure 100. In some embodiments, the substrate 200 may be a package substrate, such as a printed circuit board.

Generally speaking, during the bonding process of the flip-chip structure 100 and the substrate 200, the stress of the bonding process may cause the damage of the passivation layer 144 if the passivation layer 144 is not well protected or the passivation layer 144 is formed at vulnerable position, such as formed at the corner C and overlapping the dummy bump 150B. Specifically, the stress may concentrate at the active bump 150A and the dummy bump 150B. The dummy bump 150B overlapping the protrusion 140P of the passivation structure 140, especially the corner C, may lead to the stress concentration at the corner C, and cause the crack of the passivation layer 144 at the corner C. In the embodiment shown in FIGS. 10-15, although the passivation layer 144 is formed at the corner C, the buffer layer 142 is able to provide a buffer from the stress from the bonding process, and the relative replacement between the passivation layer 144 and the organic layer 146 is reduced during the bonding process. The passivation layer 144 is less likely damaged during the bonding process, thereby the moisture isolation of the passivation structure 140 still remaining at the same level after the bonding process.

As mentioned above, a passivation structure used in a flip-chip structure includes a buffer layer with higher malleability to reduce the possibility of the crack of the passivation layer during the bonding process. The buffer layer may be provided between the passivation layer and the metal line layer, such that the passivation layer may be formed as a flat layer. The buffer layer may also be provided between the passivation layer and the dummy bump, such that the buffer layer provides a buffer from the stress from the bonding process. The moisture isolation of the resulting passivation structure still remains at the same level after the bonding process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a substrate;
a dielectric layer over the substrate;
a metal line layer over the dielectric layer, wherein the metal line layer comprises a via portion penetrating the dielectric layer;
a passivation structure over the metal line layer, wherein the passivation structure comprises a protrusion surrounded by the via portion of the metal line layer and a horizontal portion of the protrusion;
an active bump penetrating the passivation structure to electrically connect to the metal line layer; and
a dummy bump over the passivation structure, wherein the dummy bump overlaps the protrusion of the passivation structure in a cross-section view.

2. The semiconductor device of claim 1, wherein a bottom surface of the horizontal portion and a sidewall of the protrusion of the passivation structure defines a corner, and the dummy bump further overlaps the corner in the cross-section view.

3. The semiconductor device of claim 1, wherein the passivation structure has a dual-layer structure.

4. The semiconductor device of claim 1, wherein the passivation structure comprises:
a buffer layer; and
a passivation layer over the buffer layer, wherein a malleability of the passivation layer is lower than a malleability of the buffer layer.

5. The semiconductor device of claim 4, wherein a bottommost surface of the passivation layer is higher than a topmost surface of the metal line layer.

6. The semiconductor device of claim 1, wherein the protrusion of the passivation structure has a void.

7. The semiconductor device of claim 1, wherein the passivation structure comprises:
a passivation layer; and
a buffer layer over the passivation layer, wherein a malleability of the passivation layer is lower than a malleability of the buffer layer.

8. The semiconductor device of claim 7, wherein a thickness of the passivation layer is less than a thickness of the buffer layer.

9. The semiconductor device of claim 7, wherein the passivation structure further comprises:
an organic layer between the buffer layer and the dummy bump, wherein a malleability of the organic layer is higher than the malleability of the buffer layer.

10. The semiconductor device of claim 9, wherein the protrusion of the passivation structure comprises a portion of the organic layer.

11. A manufacturing method of a semiconductor device, comprising:
forming a dielectric layer having an opening over a first substrate;
forming a metal line layer lining the dielectric layer and the opening;
forming a passivation structure over the metal line layer, wherein the passivation structure overfills the opening and forms a protrusion in the opening and a horizontal portion over the protrusion;
forming an active bump penetrates through the passivation structure to electrically connect the metal line layer; and
forming a dummy bump over the passivation structure, wherein the dummy bump overlaps the protrusion of the passivation structure in a cross-section view.

12. The manufacturing method of claim 11, wherein a bottom surface of the horizontal portion and a sidewall of the protrusion of the passivation structure defines a corner, and the dummy bump further overlaps the corner in the cross-section view.

13. The manufacturing method of claim 11, wherein forming the passivation structure comprises:
forming a buffer layer over the metal line layer and overfilling the opening; and
forming a passivation layer over the buffer layer, and a malleability of the passivation layer is lower than a malleability of the buffer layer.

14. The manufacturing method of claim 13, wherein forming the passivation structure further comprises:
performing a planarization process to the buffer layer prior to forming the passivation layer.

15. The manufacturing method of claim 13, wherein a bottommost surface of the passivation layer is higher than a topmost surface of the metal line layer.

16. The manufacturing method of claim 11, wherein a void is formed in the protrusion of the passivation structure.

17. The manufacturing method of claim 11, wherein forming the passivation structure comprises:
forming a passivation layer lining the metal line layer; and
forming a buffer layer lining the passivation layer, wherein a malleability of the buffer layer is higher than a malleability of the passivation layer.

18. The manufacturing method of claim 17, wherein the protrusion of the passivation structure comprises a portion of the passivation layer and a portion of the buffer layer.

19. The manufacturing method of claim 17, wherein forming the passivation structure further comprises:
forming as organic layer over the buffer layer and overfilling the opening, wherein a malleability of the organic layer is higher than the malleability of the buffer layer.

20. The manufacturing method of claim 11, further comprising:
bonding the active bump and the dummy bump to a second substrate.
